(19) United States
(12) Patent Application Publication
(10) Pub. No.: US 2025/0060176 A1
(43) Pub. Date: Feb. 20, 2025

(54) DUAL-CHANNEL FLOW BOILING SYSTEM WITH FUNCTIONALIZED SURFACES

(71) Applicant: NUTech Ventures, Inc., Lincoln, CA (US)

(72) Inventors: Logan Pettit, Lincoln, NE (US); George Gogos, Lincoln, NE (US); Craig Zuhlke, Lincoln, NE (US)

(21) Appl. No.: 18/804,671

(22) Filed: Aug. 14, 2024

Related U.S. Application Data
(60) Provisional application No. 63/519,616, filed on Aug. 15, 2023.

(51) Int. Cl. F28F 13/18

(52) U.S. Cl. CPC F28F 13/187

(57) ABSTRACT

Systems and methods for transferring heat from a heat source using a dual-channel flow boiling structure having a first fluid flow channel configured to receive a flow of a first fluid in a first direction, a second fluid flow channel configured to receive a flow of a second fluid in a second direction, parallel or counterflow to the first direction, and a separator condenser separating the first fluid flow channel and the second fluid flow channel. Opposing sides of the separator condenser define a flow surface of the first fluid flow channel and a flow surface of the second fluid flow channel. One or both opposing sides of the separator condenser has a functionalized surface that includes micro-scale and nano-scale features formed by femtosecond laser surface processing (FLSP) or any other functionalization technique, and/or a surface of the first fluid flow channel other than the flow surface defined by the separator condenser is a functionalized surface that includes micro-scale and nano-scale features.

### CROSS-REFERENCE TO RELATED APPLICATIONS

This application claims the benefit of priority to U.S. Provisional Patent Application No. 63/519,616, filed Aug. 15, 2023, titled “DUAL-CHANNEL FLOW BOILING SYSTEM WITH FUNCTIONALIZED SURFACES”, which is hereby incorporated by reference in its entirety.

### FEDERALLY SPONSORED RESEARCH OR DEVELOPMENT

This invention was made with Government support under contract NNX15AI09H awarded by The National Aeronautics and Space Administration and with Government support under contract NSTGRO: 80NSSC21K1295 awarded by The National Aeronautics and Space Administration, and with Government support under contract N00014-20-1-2025 awarded by the Office of Naval Research. The Government has certain rights in this invention.

### BACKGROUND

The present disclosure provides systems and methods for heat exchange using a dual channel flow-boiling device with functionalized surfaces.

Future technology advancements that can lead to higher performing components are often hindered by thermal management issues, such as the ability to dissipate large heat fluxes and the ability to simultaneously maintain material temperatures below prescribed limits [1]. Satellite and spacecraft avionics, computer data centers, supercomputers, hybrid vehicle power electronics, X-ray medical equipment, heat exchangers for hydrogen storage and for high Mach aircraft engines and rocket nozzles are some of the technologies that depend on transformative advancements in thermal management to leap forward in tandem. Because many of the components in these technologies are small, they require compact solutions that can dissipate large heat fluxes with very high heat transfer efficiency over a small area. The development of flow boiling in mini/micro sized channels is a promising avenue to dissipate extreme heat fluxes of the future. Compared to single phase flow, it offers intrinsic advantages for approaching the heat transfer demand because it takes advantage of the latent heat of vaporization of a fluid, and its geometries and surface morphology give rise to a large ratio of surface area to working fluid volume, both of which have the potential to increase heat transfer efficiency while at the same time keeping the surface temperature low. However, there still exists the need for transformative improvement in both heat transfer capabilities and flow instability mitigation.

One avenue widely studied for the enhancement of flow boiling is surface modification. Many different micro- and nano-scale surface functionalization techniques exist and have been investigated in the past. Some of the more heavily studied schemes include micro-fins [2-5], nanoscale coatings [6-9], and porous coatings and foams [10-12].

Micro-fins are one method of surface functionalization commonly fabricated using laser micro milling and wire-cut electro-discharge machining. Mechanisms responsible for heat transfer enhancement vary among experiments, but include increasing the heat transfer area, reducing vapor build up and combatting inferior flow patterns, providing stable nucleation sites, and introducing wicking for liquid rewetting. Law and Lee reported enhancement up to 6.2- and 2.8-times for the heat transfer coefficient (HTC) and critical heat flux (CHF), respectively, using oblique-finned microchannels [2]. They also found that compared to straight-finned microchannels, the oblique-finned microchannels produced a 4 times smaller standard deviation of the pressure fluctuations. Wan et al. studied the performance of four different staggered micro pin-fin shapes and found that the square fins had the best performance in terms of both heat transfer and flow instability mitigation [3]. Woodcock et al. designed and investigated ‘piranha’ shaped pin-fins for dissipating high heat fluxes, and achieved a CHF of 676 W/cm² using HFE-7100 [4]. Deng et al. studied conical micro pin-fins created on the bottom surface of microchannels and observed up to 175% heat transfer coefficient enhancement with ethanol compared to conventional rectangular microchannels [5]. They also noted increases in CHF and mitigation of flow instabilities.

Another method of surface modification shown to improve heat transfer performance is nanoscale coatings, which increase the heat transfer area and nucleation site density and modify the surface wettability. Yang et al. coated parallel microchannels in silicon nanowires and reported a 344% enhancement in the HTC and a 14.9% enhancement in the CHF compared to plain-wall microchannels [6]. Morshed et al. grew copper nanowires on the bottom surface of a single microchannel and found a 56% enhancement in the HTC, but no improvement to CHF was noted [7]. Morshed et al. also tried coating the microchannel with a Cu-Al₂O₃ nanocomposite and observed up to 120% enhancement in the HTC and 55% enhancement in the CHF [8]. Khanikar et al. performed experiments using carbon nanotube coatings on a copper microchannel [9]. They reported up to a 23% enhancement in CHF but noted substantial degradation after repeated testing.

Porous coatings and foams used in flow boiling channels have been shown to enhance heat transfer by augmenting the area available for heat transfer and increasing the number/density of nucleation sites. Pranoto and Leong investigated the effects of inserting a porous graphite foam into a flow boiling channel and observed up to 2.5 times increase in HTC [10]. Sun et al. varied the structural parameters of a microporous coating made from copper particles sintered on the bottom wall of a minichannel [11]. They observed up to a 692% enhancement in the HTC and up to 20% enhancement in the CHF compared to an uncoated surface. Lee et al. studied the effects of a porous copper nickel alloy coating on all three walls of a copper microchannel array and observed up to a 43.5% enhancement in HTC [12].

Although there are numerous surface functionalization techniques that have shown substantial flow boiling enhancement, they have not been tested for structural permanency and are not scalable for industrial settings. Accordingly, improved functionalization techniques and devices benefitting from the same are needed.

### SUMMARY

The present embodiments provide systems and methods for heat exchange using a dual channel flow-boiling device with functionalized surfaces.

According to an embodiment, a novel counterflow dual-channel flow boiling system is provided that includes a boiling stream adjacent to the heat source and a cold stream adjacent to the boiling stream in a counterflow configuration. The surface of the boiling channel adjacent to the heat source may be functionalized, e.g., modified using femtosecond laser surface processing (FLSP) or other functionalization technique, which creates microstructures with or without nanoscale structures on the microstructures that introduce additional nucleation sites having a wide range of sizes, produce superhydrophilic wetting properties, and augment the surface area available for two-phase heat transfer. A condenser plate separating the boiling stream and the cold stream may be functionalized on one or both sides, e.g., the sides facing one or both of the boiling stream and the cold stream. The functionalized surfaces may include any material such as a ceramic material or a metallic material like 304 stainless steel, and the working fluid(s) may include water, a dielectric fluid and/or a refrigerant. The working fluids may be the same in each of the cold stream and the boiling stream, or they may be different.

According to an embodiment, a dual-channel flow boiling device is provided that includes a first fluid flow channel configured to receive a flow of a first fluid and flow the first fluid in a first direction, a second fluid flow channel adjacent the first fluid flow channel and configured to receive a flow of a second fluid and flow the second fluid in a second direction, and a separator condenser separating the first fluid flow channel and the second fluid flow channel, wherein the separator condenser has one or more functionalized surfaces, and wherein the separator condenser is integral to both the first fluid flow channel and the second fluid flow channel.

In certain aspects, the second fluid flow received at the second fluid flow channel is maintained at a lower temperature than the first fluid flow received at the first fluid flow channel to cause condensation of the first fluid in the first fluid flow channel.

In certain aspects, the functionalized surfaces include micro-scale and nano-scale features formed by femtosecond laser surface processing (FLSP) or any other form of functionalization.

In certain aspects, the device further includes a heat source adjacent the first fluid flow channel, wherein a surface of the first fluid flow channel proximal to the heat source has a functionalized surface including micro-scale and nano-scale features formed by femtosecond laser surface processing (FLSP) or any other form of functionalization.

According to an embodiment, a method is provided for transferring heat from a heat source using a dual-channel flow boiling structure having a first fluid flow channel configured to receive a flow of a first fluid in a first direction, a second fluid flow channel configured to receive a flow of a second fluid in a second direction, and a separator condenser separating the first fluid flow channel and the second fluid flow channel, wherein opposing sides of the separator condenser define a flow surface of the first fluid flow channel and a flow surface of the second fluid flow channel, wherein one or both opposing sides of the separator condenser has a functionalized surface that includes micro-scale and nano-scale features formed by femtosecond laser surface processing (FLSP) or any other functionalization technique, wherein the first fluid flow channel has a functionalized surface other than the flow surface defined by the separator condenser that includes micro-scale and nano-scale features formed by FLSP or any other functionalization technique. The method includes positioning the dual-channel flow boiling structure proximal to a heat source such that the functionalized surface of the first fluid flow channel is located proximal to the heat source, flowing the first fluid in the first fluid flow channel, and simultaneously flowing the second fluid in the second fluid flow channel, wherein the second fluid received at the second fluid flow channel is maintained at a lower temperature than the first fluid received at the first fluid flow channel causing condensation on the flow surface of the separator condenser facing the first fluid flow channel.

According to an embodiment, a dual-channel flow boiling system is provided that includes a dual-channel flow boiling device and at least one pump. The dual-channel flow boiling device includes a first fluid flow channel configured to receive a flow of a first fluid in a first direction, a second fluid flow channel adjacent the first fluid channel and configured to receive a flow of a second fluid in a second direction, and a separator condenser separating the first fluid flow channel and the second fluid flow channel, wherein opposing sides of the separator condenser define a flow surface of the first fluid flow channel and a flow surface of the second fluid flow channel, wherein one or both opposing sides of the separator condenser has a functionalized surface that includes micro-scale and nano-scale features formed by femtosecond laser surface processing (FLSP) or any other functionalization technique, and wherein the first fluid flow channel has a functionalized surface, other than the flow surface defined by the separator condenser that includes micro-scale and nano-scale features formed by FLSP or any other functionalization technique. The at least one pump is configured to generate a flow of a first fluid through the first fluid flow channel from a first fluid source, and to generate a flow of a second fluid through the second fluid flow channel from a second fluid source, wherein the second fluid source is maintained at a colder temperature than the first fluid source.

In certain aspects, the at least one pump includes a first pump configured to generate the flow of the first fluid through the first fluid flow channel from the first fluid source; and a second pump configured to generate the flow of the second fluid through the second fluid flow channel from the second fluid source.

According to an embodiment, a dual-channel flow boiling system is provided that includes a dual-channel flow boiling device and at least one pump. The dual-channel flow boiling device includes a first fluid flow channel configured to receive a flow of a first fluid in a first direction, a second fluid flow channel adjacent the first fluid channel and configured to receive a flow of a second fluid in a second direction, and a separator condenser separating the first fluid flow channel and the second fluid flow channel, wherein opposing sides of the separator condenser define a flow surface of the first fluid flow channel and a flow surface of the second fluid flow channel, wherein at least one of the opposing sides of the separator condenser has a functionalized surface that includes micro-scale and nano-scale features, or a surface of the first fluid flow channel other than the flow surface defined by the separator condenser is a functionalized surface that includes micro-scale and nano-scale features. The at least one pump is configured to generate a flow of a first fluid through the first fluid flow channel from a first fluid source, and to generate a flow of a second fluid through the second fluid flow channel from a second fluid source, wherein the second fluid source is maintained at a colder temperature than the first fluid source.

In certain aspects, one or both opposing sides of the separator condenser has a functionalized surface that includes micro-scale and nano-scale features formed by femtosecond laser surface processing (FLSP) or any other functionalization technique.

In certain aspects, one or both opposing sides of the separator condenser has a functionalized surface that includes micro-scale and nano-scale features formed by femtosecond laser surface processing (FLSP) or any other functionalization technique and the surface of the first fluid flow channel other than the flow surface defined by the separator condenser is a functionalized surface that includes micro-scale and nano-scale features formed by FLSP or any other functionalization technique.

In certain aspects of the embodiments, the first fluid and the second fluid each comprise deionized water, a dielectric fluid or a refrigerant.

In certain aspects of the embodiments, the first fluid is different than the second fluid.

In certain aspects of the embodiments, the separator condenser comprises a metal material, a ceramic material or a plastic material.

In certain aspects of the embodiments, the separator condenser comprises a sheet of 304 stainless steel.

In certain aspects, the sheet of 304 stainless steel has a uniform thickness of from about 250 μm to about 2 mm.

In certain aspects, the micro-scale and nano-scale features of the functionalized surface have an average structure height of between about 20 μm to 100 μm, and an average roughness of from about 6 μm to about 7 μm

In certain aspects of the embodiments, the flow of the second fluid in the second direction is opposite the flow of the first fluid in the first direction. For example, vectors representing the flows in the first direction and the second direction are substantially anti-parallel.

In certain aspects, the flow of the second fluid in the second direction is parallel to and in a same direction as the flow of the first fluid in the first direction. For example, vectors representing the flows in the first direction and the second direction are substantially parallel.

Reference to the remaining portions of the specification, including the drawings and claims, will realize other features and advantages of the present invention. Further features and advantages of the present invention, as well as the structure and operation of various embodiments of the present invention, are described in detail below with respect to the accompanying drawings. In the drawings, like reference numbers indicate identical or functionally similar elements.

### BRIEF DESCRIPTION OF THE SEVERAL VIEWS OF THE DRAWINGS

The detailed description is described with reference to the accompanying figures. The use of the same reference numbers in different instances in the description and the figures may indicate similar or identical items.

FIG. 1 illustrates a cross section of a dual-channel flow boiling heat exchanger device 100 according to an embodiment

FIG. 2 shows a schematic of an example FLSP setup.

FIG. 3. Shows scanning electron microscopy (SEM) images of a resulting surface.

FIG. 4 shows a schematic of a dual-channel experimental setup.

FIG. 5 shows an exploded view of a dual-channel test section according to an embodiment.

FIG. 6 shows a cross section of the dual-channel test section according top an embodiment.

FIG. 7 shows a schematic of the subcooled region in the dual-channel test section according to an embodiment.

FIG. 8, panel (a) shows boiling curves and panel (b) shows HTC versus heat flux curves at sample location 4 for each test (SC and DC indicate single-channel and dual-channel, respectively).

FIG. 9, panel (a) shows boiling curves and panel (b) shows HTC versus heat flux curves at sample location 6 for each test (SC and DC indicate single-channel and dual-channel, respectively).

FIG. 10 shows time plots of inlet pressure oscillations at three different heat fluxes (SC and DC indicate single-channel and dual-channel, respectively).

FIG. 11 shows the standard deviation of inlet pressure oscillations versus average heat flux (SC and DC indicate single-channel and dual-channel, respectively).

### DETAILED DESCRIPTION

The following detailed description is exemplary in nature and is not intended to limit the invention or the application and uses of the invention. Furthermore, there is no intention to be bound by any expressed or implied theory presented in the following detailed description or the appended drawings.

Turning to the drawings, and as described in detail herein, embodiments of the disclosure provide systems and methods for heat exchange using a dual channel flow-boiling device with functionalized surfaces.

FLSP can functionalize a surface in a quick, single-step process that offers precision and repeatability while creating permanent surface structures with characteristics beneficial to boiling heat transfer. Laser processing can increase the heat transfer area and nucleation site density by augmenting surface roughness and can modify the surface wettability and capillary wicking capabilities. Kruse et al. studied the effects of femtosecond laser surface processing (FLSP) on pool boiling experiments using 304 stainless steel surfaces with water [13]. They observed up to 193% enhancement in the maximum HTC and up to 56% enhancement in the CHF. The HTC enhancement was attributed to the increase in surface area and active nucleation site density, and the CHF enhancement was attributed to the increase in wettability and wicking capabilities of the FLSP surface. In a follow-up study, Kruse et al. investigated boiling inversion (superheat decrease with increasing heat flux) by varying the metal used for the boiling surface and the microstructure height created with FLSP [14]. They determined that boiling inversion resulted from temperature gradients along the microstructures for lower thermal conductivity metals and the activation of smaller nucleation cavities as heat flux increases. The inversion resulted in higher rates of HTC enhancement at higher heat fluxes. Costa-Greger et al. investigated the effects of FLSP on 6061 aluminum surfaces in pool boiling experiments with PF-5060 as the working fluid [15]. They reported HTC enhancement up to 680%. The observed enhancement was attributed to the abundance of potential nucleation sites formed during FLSP. A recent study by Lim et al. used a femtosecond laser to functionalize a copper flow boiling surface [16]. Although the laser processed surfaces yielded heat transfer enhancement, they did not resemble the characteristic structures produced by FLSP. Thus far, previous studies using FLSP surfaces have been limited to pool boiling experiments.

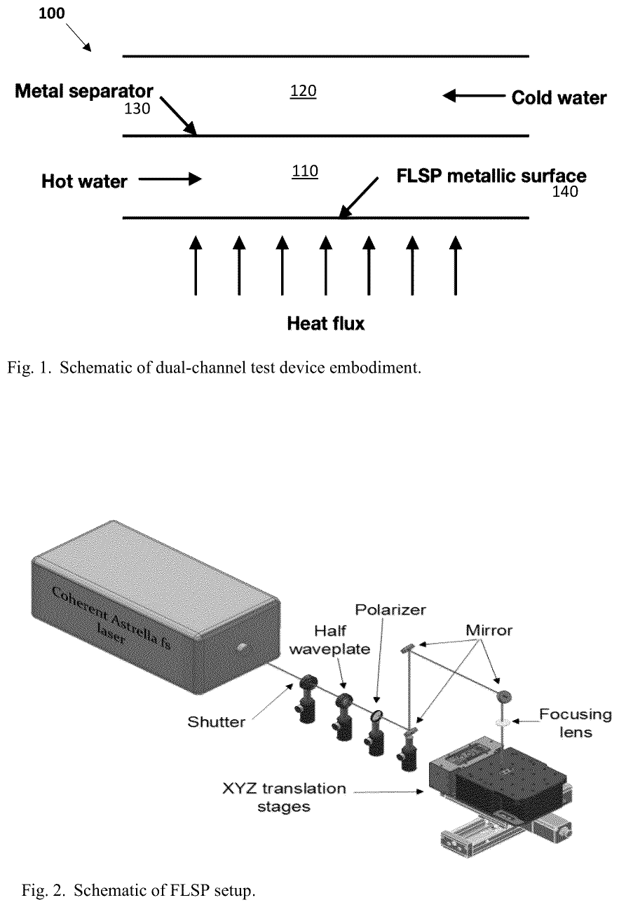

FIG. 1 illustrates a cross section of a dual-channel flow boiling heat exchanger device 100 according to an embodiment. As shown in FIG. 1, a cold (counterflow) fluid flow channel 120 is provided immediately adjacent to a main (hot) fluid flow channel 110. Separating the two fluid streams, and defining a common wall (or a portion of a common wall) of both channels is a separator condenser 130 including a material that acts as a condenser for fluid flowing in the main fluid flow channel 110. For example, in an embodiment, the separator condenser 130 may include a metal separator, e.g., a thin (e.g., 1.22 mm) plate or sheet 130, e.g., a 304 stainless steel plate, that acts as a condenser plate for fluid flowing in the main fluid flow channel 110. A thin plate or sheet 140, e.g., a 304 stainless steel plate, forms the heat transfer wall or surface of the main (hot) fluid flow channel 110 to be positioned proximal to the heat source (shown as heat flux in FIG. 1). In use, the dual-channel flow boiling heat exchanger device 100 is placed with surface 140 proximal a heat source to remove or dissipate heat from the heat source. It should be appreciated that each of the plate or sheet 130 and the plate or sheet 140 may include metal materials such as stainless steel, e.g., 304 stainless steel, or other materials such as any metals, or any ceramics. The cross-sectional shape of each of the fluid flow channels 110 and 120 may take on any shape, such as round, oval, rectangular, etc.

In an embodiment, the plate or sheet 130 has a high thermal conductivity, e.g., ≥10 W/(m×° K). In an embodiment, the plate or sheet 130 (on one or both sides) and/or the plate or sheet 140 may be, or may have been, functionalized. In an embodiment, functionalization may be done using femtosecond laser surface processing (FLSP), a laser processing technique that uses ultra-short laser pulses to create self-organized, quasi-periodic, micro- and nano-scale structures. In other embodiments, the surface(s) may be functionalized using any other functionalization technique known to one skilled in the art, such as chemical etching, laser processing (femtosecond laser surface processing or non-femtosecond laser surface processing), etc. For laser processing, any laser, including a continuous wave (cw) laser, may be used, however, functionalized surface parameters may be more easily optimized using a femtosecond laser.

In an embodiment, fluids flowing in the fluid flow channel 120 and the fluid flow channel 110 may include water (e.g., deionized water), a dielectric fluid or a refrigerant. The fluids in fluid flow channel 110 and fluid flow channel 120 may be the same or they may be different.

The formed hierarchical structures may be made directly from the substrate material in a single step process. For example, FLSP is capable of creating a wide range of surface morphologies that can be used for two-phase heat transfer devices herein. These surfaces contain micro- and nano-scale structures that range anywhere from tall and narrow to short and mound-like, and are often blanketed with a layer of nanoparticles. The two primary parameters that determine the structures produced on a surface, such as a metallic surface, are laser fluence and pulse count. Laser fluence is the amount of laser energy delivered to the surface per unit area, and pulse count is the number of laser interactions with a given area. These parameters may be varied to create microstructures with different shapes and sizes, and different nanoparticle layer thicknesses. The surfaces created often have competing boiling enhancement mechanisms, which is primarily due to the presence of the porous nanoparticle layer. This layer provides additional nucleation sites and increases the capillary wicking of the surface, thus enhancing the two-phase heat transfer. However, the nanoparticle layer is porous, and adds additional thermal resistance to the surface, which combats the two-phase heat transfer enhancement. The wide parameter variation of FLSP allows for in depth investigation and implementation of the optimal parameter combinations whose corresponding surface morphology balances these two mechanisms.

In some embodiments, a change in chemistry of the processed surface, such as oxidation of a metallic or ceramic surface, may be controlled by controlling the process environment.

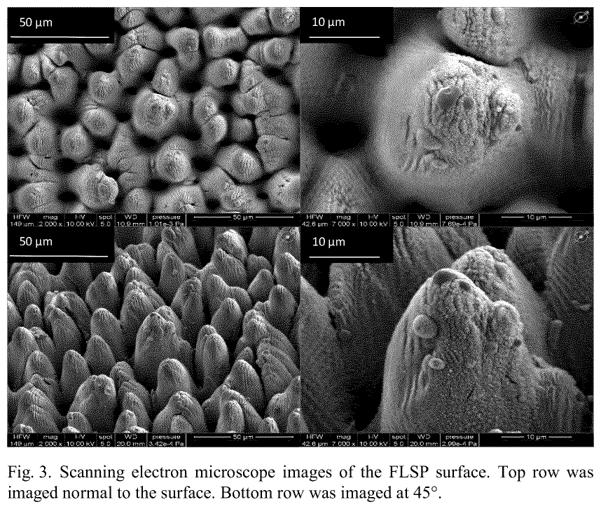

A schematic of an example FLSP setup is shown in FIG. 2. The FLSP setup includes a pulsed laser source having parameters including a central wavelength, a pulse length, a maximum pulse energy and a repetition rate. Any one or all of these parameters may be varied. The incident beam may be focused onto the surface using various optical components such as a polarizer, one or more mirrors, one or more lenses, a half waveplate, a shutter and/or other optical components as would be well known to one skilled in the art. X-Y-Z translation stages enable rastering of the pulsed beam across the surface being processed or alternatively a galvoscanner can be used to move the laser beam relative to the surface.

In various embodiments, the pulsed laser beam is a femtosecond laser beam and any method involving FLSP includes a step of applying femtosecond laser surface processing (FLSP) with the controlled fluence to a region of the metallic surface. Optionally, the applying FLSP with a controlled fluence includes applying a series of laser pulses having a peak fluence of between 0.3±20% J/cm² to 5.0±20% J/cm². Optionally, the fluence is between 2.5±20% J/cm² to 3.0±20% J/cm². Optionally, each of the pulses has a same wavelength of between 100±20% nm and about 21,000±20% nm. Optionally, each of the pulses has a same peak wavelength (i.e., wavelength at peak light intensity) of between 100±20% nm and about 21,000±20% nm. Optionally, each of the pulses has a same wavelength of 800±20% nm. Optionally, each of the pulses has a same peak wavelength of 800±20% nm. In general, it is understood that FLSP is fairly wavelength independent and may be more dependent on the time scale of the pulse. In certain aspects, other parameters could be changed to change the fluence needed (e.g., processing at a different wavelength, repetition rate or pulse length; processing using multiple pulses with lower individual energy but similar total energy; processing in different atmospheres; processing with the sample at different temperatures, etc.).

Optionally, any surface processing method disclosed herein may comprise scanning (e.g., rastering) the pulsed laser beam on the surface being processed during a step of irradiating thereby exposing a plurality of locations to the pulsed laser beam. Optionally, scanning (or, rastering) the pulsed laser beam may be accomplished or performed by (1) translating the laser beam and/or adjusting an angle of the laser beam at the layer or surface being irradiated, such as by using one or more mirrors to direct the laser beam, and/or by (2) changing a location of the irradiated layer or surface relative to a location of the laser beam, such as using a movable/translatable and/or tiltable sample stage. Optionally, in any method disclosed herein, the step of scanning is characterized by a scan speed selected from the range of 0.01 mm/s to 10 m/s, optionally any value or range therebetween inclusively. Optionally, in any method disclosed herein, the pulsed laser beam is characterized by a pulse frequency selected from the range of 1 Hz to 100 MHz, optionally any value or range therebetween inclusively. Optionally, in any method disclosed herein, the pulsed laser beam is characterized by a pulse energy selected from the range of 1 nJ to 30 J, optionally any value or range therebetween inclusively. Optionally, in any method disclosed herein, the pulsed laser beam is characterized by a fluence selected from the range of 0.01 J/cm² to 100 J/cm², optionally any value or range therebetween inclusively. Optionally, in some methods disclosed herein, the step of irradiating is characterized by a pulse length selected from the range of 1 fs to 10 ps, optionally selected from the range of 10 ps to 100 ns, optionally selected from the range of 1 fs to 100 ns, or optionally any value or range therebetween inclusively. Optionally, in any method disclosed herein, the step of irradiating is characterized by a spot density selected from the range of 10 to 50,000 spots/mm², optionally 10 to 50,000 spots/cm², optionally any value or range therebetween inclusively, optionally 10 to 50,000 spots/dm², optionally 10 to 50,000 spots/m², optionally 10 to 50,000 spots/m². Optionally, in any method disclosed herein, the step of irradiating is characterized by a spot density selected from the range of 10 to 5,000,000 spots/cm², optionally any value or range therebetween inclusively, such as optionally 10 to 500,000 spots/cm², optionally 100 to 500,000 spots/cm², optionally 1000 to 500,000 spots/cm², optionally 1000 to 300,000 spots/cm², optionally 10,000 to 500,000 spots/cm².

Optionally, the step of irradiating is characterized by a pulse count of from 1 to 40,000,000. Pulse count is defined as the number of times each location on the sample is illuminated by a pulse and is independent of the area. The pulse count range can be from 1 to 40,000,000. The upper limit is based on the laser repetition rate and should not be limited because the repetition rate of lasers is increasing rapidly. For direct writing the pulse count can be very high. Practical applications typically are in the range of 100 to 30,000. For applications in enhancing heat transfer, the pulse count is usually in the range of 200 to 3,000.

Optionally, in any method disclosed herein, the pulsed laser beam is characterized by an average spot size selected from the range of 100 nm to 1 cm, optionally any value or range therebetween inclusively, such as optionally 1 μm to 1000 μm or optionally 1 μm to 1 cm. In some embodiments, parameters of the step of irradiating and of the pulsed beam laser may be controlled independently, including but not limited to, scan speed, pulse energy, fluence, spot size, pulse length, pulse count, pulse density or pulses-per-area, and pulse frequency, to tune parameters of the microfeatures, including, but not limited to, thickness of one or more microfeature layers, microstructure of one or more microfeature layers, presence or absence and microstructure of the redeposited surface layer, peak-to-valley height, and presence or absence or thickness of an interfacial layer. In some embodiments, some parameters of the pulsed laser beam may be interdependent, such as scan velocity and repetition rate of the pulsed laser beam or pulse energy and beam diameter or spot size. Optionally, in any method disclosed herein, formation of the plurality of microfeatures during the step of irradiating comprises ablation (e.g., “valley ablation”) of portions of the starting single- or multi-layer material that surround each microfeature.

Optionally, in any method, nano-scale or micro-scale feature(s) (hereinafter also referred to as “microfeature(s)”), composition, material, and system disclosed herein, each microfeature has a peak-to-valley height selected from the range of 1 μm to 2 mm, e.g., 1 μm to 1.75 mm, or 1 μm to 1 mm, or 1 μm to 500 μm, optionally any value or range therebetween inclusively. Optionally, in any method, microfeature(s), composition, material, and system disclosed herein, the microfeatures are arranged as an array on a substrate, the substrate comprising the first composition. Optionally, the array is periodic or semi-periodic. Optionally for any microfeature, each microfeature layer or each microfeature layer other than the surface redeposited-layer, if present, is in the form of a polycrystalline film. Optionally for any microfeature, each microfeature layer other than the surface redeposited-layer, if present, has a thickness selected from the range of 10 nm to 2,000 μm, optionally any thickness therebetween inclusively, optionally selected from the range of 1 μm to 2,000 μm. Optionally for any microfeature, each microfeature is a mound or pillar. Optionally for any microfeature, each microfeature has a peak-to-valley height selected from the range of 1 μm to 2,000 μm, optionally any thickness therebetween inclusively. Optionally for any microfeature, an interface between any two microfeature layers is compositionally abrupt or comprises an interfacial layer; wherein the interfacial layer has thickness less than 10 μm and has an interfacial composition comprising a mixture of a composition of each of the microfeature layers adjacent to the interfacial layer.

To test the present embodiments, preliminary results using FLSP on a 304 stainless steel surface in a flow boiling heat exchanger device using water in the fluid flow channels are presented below. The effects of the novel counterflow dual-channel flow boiling system are explored and compared to a standard single-channel system. Heat transfer performance and flow stability are compared to a polished baseline for both flow boiling systems using boiling curves, heat transfer coefficient plots, and pressure oscillation plots.

### Surface Fabrication/Processing

For designing the specific test device as will be discussed below, the laser source used to functionalize the test surfaces included a Ti:sapphire femtosecond laser (Coherent Inc. Astrella), with a central wavelength of about 800 nm, a pulse length of about 35 fs, a maximum pulse energy of about 6 mJ, and a repetition rate of about 1 kHz. The incident beam was focused onto the surface using a plano-convex lens with a 150 mm focal length. The laser parameters used for the test surfaces was a 1/e² Gaussian spot diameter of 552.5 μm, stage velocity of 6.0 mm/s, and raster pitch of 50 μm, yielding a pulse count of 646, and a peak fluence of 2.50 J/cm².

### Surface Characterization

Laser scanning confocal microscopy (LSCM, Keyence: VK-X200) was used to quantitatively measure the surface characteristics of the test surface. A total of 30 measurements were taken at different locations on the surface to obtain average values for structure height, R_{z}, average roughness, Ra, and surface area to area ratio, r, and are presented in Table 1. The FLSP process yielded a surface with an average structure height, roughness, and surface area ratio of 45.3 μm, 6.58 μm, and 10.9, respectively. Scanning electron microscopy (SEM, FEI Quanta 200 Environmental SEM) was used to qualitatively observe the resulting surface characteristics of the test sample, which is shown in FIG. 3. After FLSP, the resulting surface is covered in a quasiperiodic array of microscale, mound-like structures that are made directly from the substrate material. Covering the mounds is a layer of nanoparticles generated during processing, which result in nanoscale porosity and roughness on the surface of the microstructures. The FLSP surface was also superhydrophilic with an apparent contact angle of 0 degrees.

TABLE 1
SURFACE MORPHOLOGICAL MEASUREMENTS.

| | Peak | | | | |
|---|---|---|---|---|---|
| Sample | Fluence | Puke | R_{z} | Rₐ | |
| Name | (J/cm²) | Count | (μm) | (μm) | r |
| Polished | — | — | 0.74 ± 0.6 | 0.08 ± 0.04 | 1.0 ± 0.0 |
| FLSP | 2.50 | 646 | 45.3 ± 4.6 | 6.58 ± 0.41 | 10.9 ± 0.6 |

### Flow Loops and Test Section

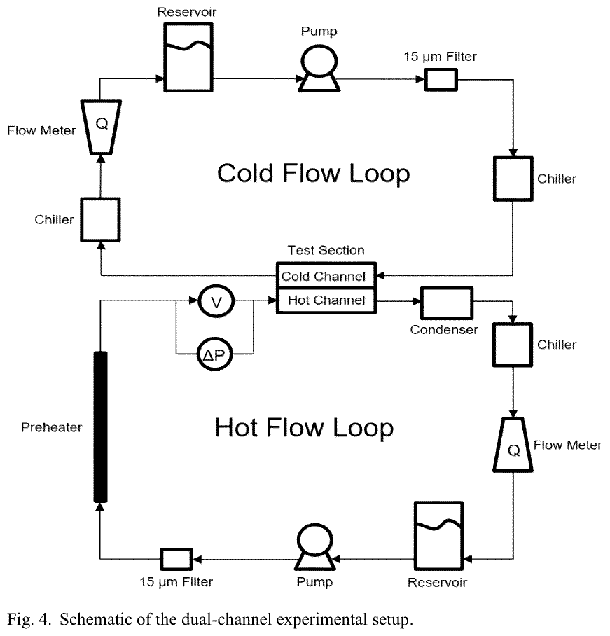

The flow loops for the dual-channel flow boiling system used for this study are shown schematically in FIG. 4. In the hot flow loop, water is housed in a stainless steel reservoir that is heated using an immersion heater powered by an analog variac power supply. Mounted on top of the reservoir is a water-cooled reflux condenser used to condense any escaping vapor during the degassing process, and a thermocouple used to measure the reservoir water temperature. The water is pumped from the reservoir with a gear pump (e.g., MICROPUMP, GA-X21.DEMSE) through a 15 μm inline filter to remove any large particulates. A preheater made from stainless steel tubing wrapped in a resistive heater is installed before the test section inlet to allow for fine adjustments in inlet temperature. Just before the test section inlet is a throttle valve with a differential pressure transducer (e.g., Omega, PX409-150DWU5V) in parallel to measure the pressure drop across the valve. Water enters the test section which is made primarily from Celazole (e.g., U-60 Unfilled PBI), a high temperature plastic, and the measurements are collected. The liquid-vapor mixture exits the test section and passes through an air-cooled condenser (e.g., LYTRON, 4105G1SB-D9) and then through a liquid bath chiller to return the water to 20° C. before passing through a digital flow meter (e.g., Omega, FLR1008) and back into the reservoir. The cold flow loop is in a counter-flow configuration for this study and is constructed in a very similar manner. The reservoir is made from HDPE (no immersion heater, condenser, or thermocouple), and the pre-heater is replaced with a liquid bath chiller to set the inlet temperature. Additionally, no condenser, throttle valve, or differential pressure transducer were included in the cold loop. All other components are identical to the hot flow loop.

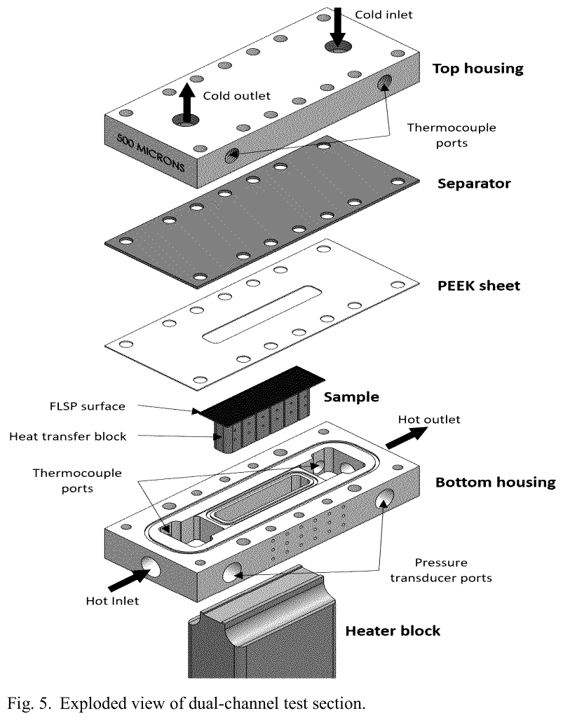

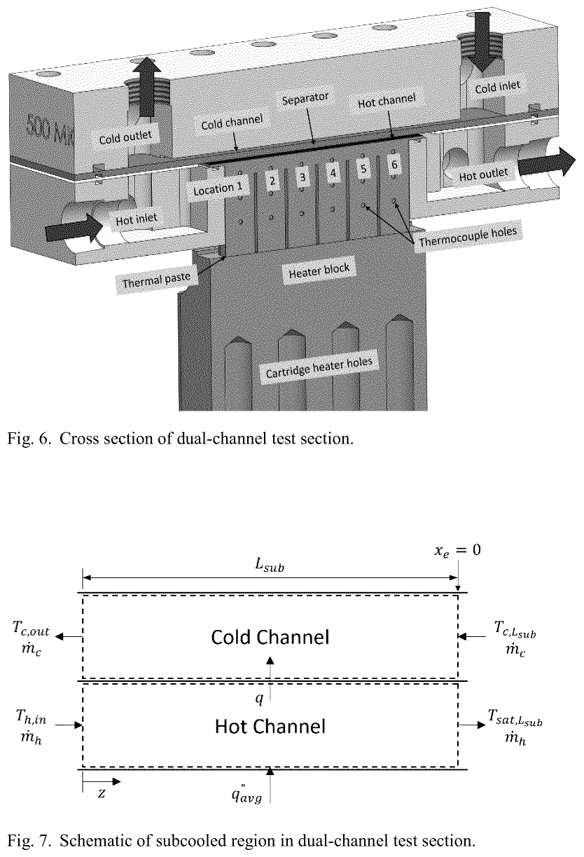

A closer look at the dual-channel test section is shown in FIG. 5 and FIG. 6. The test sample is fabricated by brazing a 500 μm thick sheet of 304 stainless steel to a 99.99% pure copper heat transfer block using a 56% silver solder paste (e.g., Muggy Weld, SSQ-6). The stainless steel test surface is oversized compared to the heat transfer block to create a lip 3.175 mm wide for an O-ring seal. The copper heat transfer block is 43.4 mm long, 8.4 mm wide, 17.78 mm tall, and is divided into six measurement locations separated by a 635 μm gap to promote 1D heat flux in each location. Each location has three equidistant holes (4.76 mm spacing) for inserting thermocouples, which are used to calculate the heat flux and to extrapolate the surface temperature at each location.

The sample is placed in a Celazole bottom housing, and the underside of the stainless steel test surface seals to the housing using an O-ring. The inlet and outlet plenums in the bottom housing have two access ports each for instrumentation. An absolute pressure transducer (e.g., Omega, PX409-100A5V) is used to measure the pressure at the test section inlet, and a differential pressure transducer (e.g., Omega, PX409-150DWU5V) is used to measure the pressure drop across the test section. A T-type thermocouple (e.g., Omega, TJ36-CPSS-116G-6) is inserted in both the inlet and outlet plenums to measure the inlet and outlet temperatures. The hot channel dimensions are machined into a thin sheet of PEEK (e.g., McMaster, 8504K115), which is placed over the bottom housing while the sample is installed and seals using an O-ring in the bottom housing. For this study, the hot channel is 500 μm tall, 8.4 mm wide, and 55.88 mm long. The heated length of the hot channel is 43.4 mm long. The channel dimensions were selected with a large aspect ratio (e.g., AR=16.8) to maximize the influence of the FLSP surface on boiling heat transfer. On top of the PEEK sheet is a flat, 1.22 mm thick separator made from 304 stainless steel. The separator contains an O-ring groove to seal against the PEEK sheet and serves as the division between the hot and cold fluids. On top of the stainless steel separator sits the top housing, which is made from Celazole and seals against the separator using an O-ring. The top housing has inlet and outlet plenums similar to the bottom housing. In each plenum are a T-type thermocouple (e.g., Omega, TJ36-CPSS-116G-6) to measure the inlet and outlet temperatures, an absolute pressure transducer (e.g., Omega, MMA030V5K3A0T4A6CE) to measure the inlet pressure, and a differential pressure transducer (e.g., Omega, MMDWB015BIV5K3COT4A6CE) to measure the pressure drop across the cold channel. The cold channel dimensions are machined into the top housing between the inlet and outlet plenums. The cold channel is 500 μm tall, 8.4 mm wide, and 68.07 mm long. Due to the presence of the PEEK sheet, the hot and cold fluid streams in the test section are insulated from each other outside of the hot channel dimensions, reducing heat losses in the device. All pieces are bolted together using a torque wrench set to 20 in-lbs. For the single-channel configuration, the stainless steel separator and the top Celazole housing are replaced with a flat piece of Celazole (not pictured) with an O-ring groove to seal against the PEEK sheet.

The sample's heat transfer block protrudes out from underneath the bottom housing when installed in the test section. The exposed underside of the heat transfer block is pressed against a heater block using bolts with a torque wrench set at 5 in-lbs., and a boron nitride thermal paste (e.g., McMaster, 3715N11) is applied between the mating surfaces to reduce the contact resistance. The heater block is made from 99.99% pure copper, and inside are twelve 150 W cartridge heaters (e.g., Omega, HDC00011). The cartridge heaters are wired in parallel and connected to an analog variac transformer.

### Operating Procedure

To begin each experiment, water in the reservoir was degassed for one hour by vigorously boiling it using the immersion heater. The water was degassed while it circulated through the hot flow loop. After degassing, the flowrate, inlet temperature, and throttle pressure drop for the hot channel were set to 60 mL/min (238 kg/s/m²), 75° C., and 500 kPa, respectively. Including a throttle valve before the inlet of the test section has been shown to reduce pressure oscillations and was included in this experiment so the oscillations were more manageable and did not exceed the rating of the pressure transducers [17]. The same hot channel parameters were used for all the single-channel and dual-channel tests. For the dual-channel tests, the flowrate and inlet temperature through the cold channel were set to 60 mL/min (238 kg/s/m²) and 10° C., respectively.

After setting the test parameters, power was applied to the cartridge heaters using the analog variac, and transient data acquisition began using a LabVIEW program. Once the temperatures in the heat transfer block reached steady state, data was recorded for 2 minutes. The two minutes of steady state data were averaged and used to generate boiling curves, heat transfer coefficient plots, and other plots presented in this study. The criterion used to define steady state was a temperature change below 0.3° C./min averaged over a three-minute moving window. Once the steady state data was obtained, the variac was increased by an increment of 5.0 Volts, and the process was repeated until the system reached critical heat flux (CHF). To determine the CHF, thirty seconds of transient data just prior to the spike in temperatures were averaged.

### Data Reduction

Three K-type thermocouples (e.g., Omega, TJ36-CAIN-032G-12) were used to obtain the temperature distribution in the heat transfer block at each of the six measurement locations. Using a one-dimensional heat conduction model and a two-point derivative approximation, the heat flux between each of the three pairs of thermocouples was found using the following equation:

$${q}_{j , kl}^{″} = - {k}_{cu} \frac{{T}_{j , k} - {T}_{j , l}}{{x}_{kl}} , 1 \leq j \leq 6 \qquad ( 1 )$$

where k_{cu} is the thermal conductivity of copper, T_{j,k} and T_{j,l} are the kth and lth thermocouple, respectively, at each sample location j, and xₖₗ is the distance between the two thermocouples. The three heat fluxes between each pair of thermocouples were then averaged to obtain q″ⱼ, the effective heat flux at the bottom of each location j of the heat transfer block, where the locations are separated by a gap width of 635 μm. At the top of the heat transfer block, the locations are not separated, and therefore the heat is conducted through a slightly larger area. The corrected surface heat flux, q″_{s,j}, at the top of the sample was calculated as

$${q}_{s , j}^{″} = {q}_{j}^{″} ( \frac{{A}_{b , j}}{{A}_{t , j}} ) \qquad ( 2 )$$

where A_{b,j} is the area at the bottom of each j location and A_{t,j} is the area at the top of each j location, which was selected as ⅙ of the total heated area at the top of the sample. The average heat flux over the entire sample, q″_{avg}, is the mean of the six surface heat fluxes. To calculate the heat transfer coefficients in the dual-channel system, the following was developed. FIG. 7 is a schematic of the subcooled region within the hot channel. An energy balance over this subcooled region yields

$${q}_{avg}^{″} {WL}_{sub} = q + {\dot{m}}_{h} {c}_{p , h} ( {T}_{sat , {L}_{sub}} - {T}_{h , in} ) \qquad ( 3 )$$

where W is the channel width, L_{sub} is the distance between the inlet and the location of zero thermodynamic equilibrium quality (xₑ=0), and \dot{m}ₕ, C_{p,h}, and T_{h,in} are the mass flow rate, specific heat, and inlet temperature for the hot channel, respectively. The heat transferred to the cold channel over the subcooled region, q, is defined as

$$q = {\dot{m}}_{c} {c}_{p , c} ( {T}_{c , out} - {T}_{c , {L}_{sub}} ) \qquad ( 4 )$$

where \dot{m}_{c}, C_{p,c}, and T_{c,out} are the mass flow rate, specific heat, and outlet temperature for the cold channel, respectively, and T_{c,L}_{_{sub}} is the temperature in the cold channel at the location of xₑ=0 in the hot channel. Both L_{sub} and T_{c,L}_{_{sub}} are unknown. Equations (3) and (4) operate under the following assumptions: 1) the pressure drop across the subcooled region of the hot channel is small and therefore the saturation temperature at xₑ=0 is determined by

$${T}_{sat , {L}_{sub}} = {T}_{sat , {P}_{in}} \qquad ( 5 )$$

where T_{sat,P}_{ᵢₙ} is the saturation temperature based on the measured inlet pressure, and 2) the heat flux between the hot and cold channels, q″, is uniform within the subcooled region. A second equation was obtained from a thermal resistance circuit between the hot and cold fluids in the subcooled region:

$$q = {UWL}_{sub} ( \overline{{T}_{h}} - \overline{{T}_{c}} ) \qquad ( 6 )$$

$$\overline{{T}_{h}} = \frac{1}{2} ( {T}_{h , in} + {T}_{sat , {L}_{sub}} ) \qquad ( 7 )$$

$$\overline{{T}_{c}} = \frac{1}{2} ( {T}_{c , out} + {T}_{c , {L}_{sub}} ) \qquad ( 8 )$$

Combining (4), (6), (7), and (8) gives

$${\dot{m}}_{c} {c}_{p , c} ( {T}_{c , out} - {T}_{c , {L}_{sub}} ) = \frac{{UWL}_{sub}}{2} [ ( {T}_{h , in} + {T}_{sat , {L}_{sub}} ) - ( {T}_{c , out} + {T}_{c , {L}_{sub}} ) ] \qquad ( 9 )$$

where U is the overall heat transfer coefficient between the hot and cold fluids. This is an additional unknown, and thus requires and additional equation. The additional equation can be obtained by applying (9) over the entire test section under single-phase flow conditions (i.e., xₑ<0 along the entire hot channel) thus giving

$${\dot{m}}_{c} {c}_{p , c} ( {T}_{c , out} - {T}_{c , in} ) = \frac{UWL}{2} [ ( {T}_{h , in} + {T}_{h , out} ) - ( {T}_{c , out} + {T}_{c , in} ) ] \qquad ( 10 )$$

where L is the heated channel length, T_{h,out} is the hot channel outlet temperature, and T_{c,in} is the cold channel inlet temperature. Equation (10) only has one unknown: U. Values for U were found by applying (10) to the lowest heat flux data point when everything is single-phase. Equations (3), (4), and (9) were then solved for L_{sub} and T_{c,L}_{_{sub}} for all two-phase data points. The local fluid temperature at each axial location within the hot channel, T_{f,j}, was then determined using (11), where zⱼ is the position of each j sample location measured relative to the upstream edge of heat transfer block (beginning of heated length). For the subcooled region, the hot fluid temperature is assumed to vary linearly and was interpolated between the inlet temperature, T_{h,in}, and the temperature at the subcooled region boundary, T_{sat,L}_{_{sub}} Similarly, the local hot fluid temperature within the saturated region was determined by a linear interpolation between the outlet temperature, T_{h,out}, and the temperature at the saturated region boundary, T_{sat,L}_{_{sub}}.

$${T}_{f , j} = \{ \begin{matrix}{T}_{h , in} + ( {T}_{sat , {L}_{sub}} - {T}_{h , in} ) \frac{{z}_{j}}{{L}_{sub}} , & {z}_{j} < {L}_{sub} \\ {T}_{sat , {L}_{sub}} + ( {T}_{h , out} - {T}_{sat , {L}_{sub}} ) \frac{{z}_{j} - {L}_{sub}}{L - {L}_{sub}} , & {z}_{j} \geq {L}_{sub}\end{matrix} \qquad ( 11 )$$

The extrapolated surface temperature at each location, T_{s,j}, was calculated using a thermal resistance circuit assuming one-dimensional heat conduction,

$${T}_{s , j} = {T}_{1 , j} - {q}_{s , j}^{″} ( \frac{{t}_{cu}}{{k}_{cu}} + \frac{{t}_{ss}}{{k}_{ss}} ) \qquad ( 12 )$$

where t_{cu} is the thickness of the copper above the top thermocouple location, t_{SS} is the thickness of the stainless steel brazed to the top of the copper, and k_{SS} is the thermal conductivity of the stainless steel. The thermal resistance of the brazing compound joining the copper and the stainless steel surface was neglected due to the high thermal conductivity and minimal thickness of the brazing material. Local heat transfer coefficients for the surface, hⱼ, were thus calculated using (13).

$${h}_{j} = \frac{{q}_{s , j}^{″}}{{T}_{s , j} - {T}_{f , j}} \qquad ( 13 )$$

Calculating the heat transfer coefficients for the single-channel system is much simpler. Because the top wall of the hot channel in the dual-channel system is replaced with an insulating material for the single-channel system, the heat transferred from the hot to the cold channel, q, equals zero. Making this substitution, (3) becomes

$${L}_{sub} = \frac{{\dot{m}}_{h} {c}_{p , h}}{{q}_{avg}^{″} W} ( {T}_{sat , {L}_{sub}} - {T}_{h , in} ) \qquad ( 14 )$$

Then, (14) was used together with (11), (12), and (13) to determine the single-channel heat transfer coefficients. The boiling curves presented in this paper plot heat flux versus the local wall superheat. The local wall superheat, ΔTⱼ, is defined as the difference between the local surface temperature and the local saturation temperature as shown in (15).

$$Δ {T}_{j} = {T}_{s , j} - {T}_{sat , j} \qquad ( 15 )$$

The local saturation temperature, T_{sat,j}, is computed using saturation tables based on data according to IAPWS IF-97. The interpolated local pressures, Pⱼ, are defined by (16), where P_{diff} is the differential pressure across the hot channel.

$${P}_{j} = \{ \begin{matrix}{P}_{in} , & {z}_{j} < {L}_{sub} \\ {P}_{in} - {P}_{diff} \frac{{z}_{j} - {L}_{sub}}{L - {L}_{sub}} , & {z}_{j} \geq {L}_{sub}\end{matrix} \qquad ( 16 )$$

### Heat Transfer

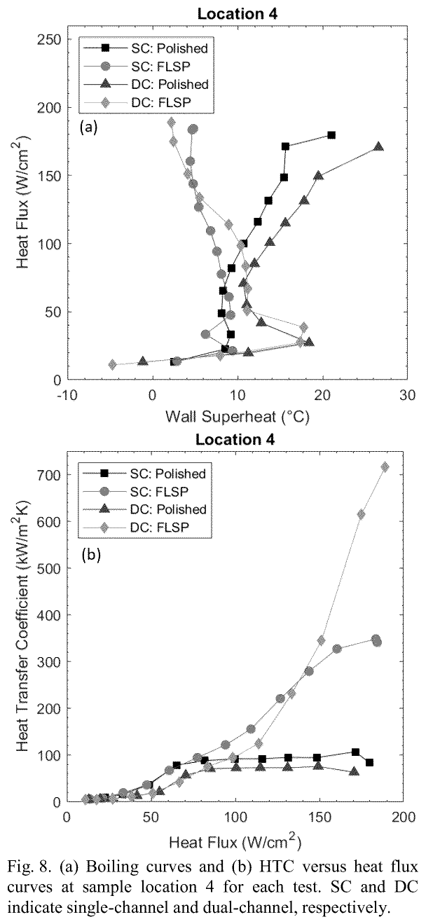

Both the polished baseline and FLSP surfaces were tested up to CHF in the single and dual-channel flow boiling systems. Boiling curves and HTCs for the four tests are plotted in FIG. 8, panel (a) and FIG. 8, panel (b), respectively, for location 4 on the sample. For the single-channel system, the polished and FLSP surfaces performed comparably up to a heat flux of around 70 W/cm². Above 70 W/cm², the boiling curves diverged, and the FLSP surface exhibited a reduction in superheat as heat flux increased, also known as boiling inversion. Boiling inversion using FLSP surfaces is a result of a change in the nucleation dynamics at higher heat fluxes [14]. The reduction in superheat resulted in substantial increases in the HTC compared to the polished surface, as shown in FIG. 8, panel (b). The maximum HTC was enhanced by 225%, reaching 348.6 kW/m².K when using the FLSP surface for the single-channel system. The observed enhancement from the FLSP surface is attributed to increases in surface area, number of potential nucleation sites, and the overall nucleation site density created during laser processing.

The dual-channel system exhibited a delay in the onset of nucleate boiling (ONB) by about 10° C., which is indicative of a higher degree of subcooling in the hot channel due to interaction with the cold channel. The polished and FLSP surfaces showed very similar results up to a heat flux of around 70 W/cm². After this point, the two boiling curves diverged, and the FLSP surface underwent boiling inversion, similar to the single-channel system. The maximum HTC was enhanced by 845%, reaching 716.0 kW/m².K when using the FLSP surface in the dual-channel system. In the dual-channel system, the FLSP surface exhibited a higher degree of boiling inversion than it did in the single-channel system, leading to lower superheats at heat fluxes above 150 W/cm² and a maximum HTC increase of 105% between systems. Identifying the mechanism responsible for the observed increase in boiling inversion present in the dual-channel system requires further study.

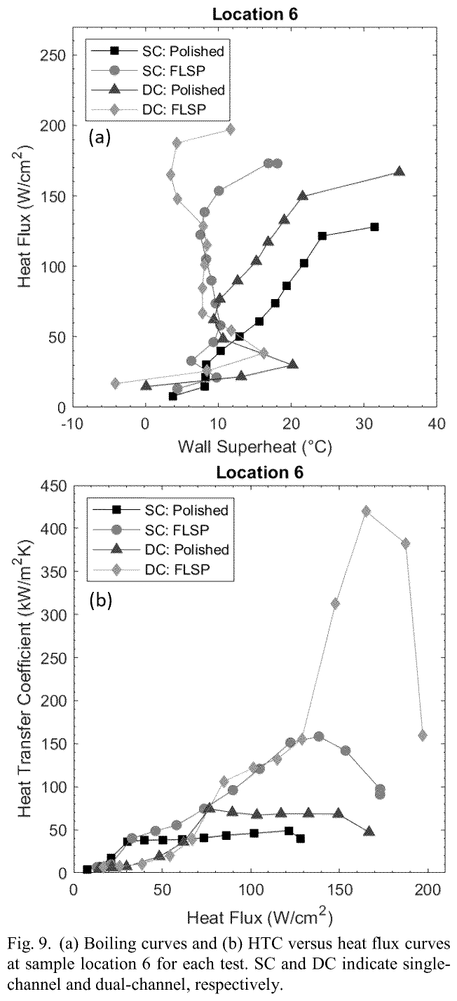

Boiling curves and HTCs for location 6 on the sample are plotted in FIG. 9, panel (a) and FIG. 9, panel (b), respectively. Comparing the single-channel polished boiling curves between locations 4 and 6, it is apparent that location 6 operated at lower heat fluxes and exhibited a substantially reduced CHF. Because location 6 is the furthest downstream, it had the highest average vapor quality of the six sample locations for a given heat flux. This in turn resulted in lower heat dissipation at the surface of location 6 and yielded a lower critical heat flux.

For the polished surface, the dual-channel system again exhibited a delay in ONB, but it also showed a reduction in the superheat after ONB and a 30% increase in CHF compared to the single-channel system, which is the inverse of what was observed at location 4. One possible explanation for the observed increase in CHF is that more condensation was occurring at the separator interface due to the presence of the cold channel, thereby reducing the accumulation of vapor in the channel and delaying dryout. Another possibility is that the enhanced CHF was a result of increasing the degree of subcooling in the channel from the interaction with the cold channel, which has been noted by some authors to delay CHF [18].

Similar to location 4, the FLSP surface exhibited some degree of boiling inversion for both systems compared to their polished counterparts, resulting in lower wall superheats and thus enhancements in HTCs. The FLSP surface yielded a 223% increase in the maximum HTC for the single-channel system, and a 465% increase in the maximum HTC for the dual-channel system. Once again, the FLSP surface exhibited a higher degree of boiling inversion in the dual-channel system than in the single-channel system, yielding a 165% increase in the maximum HTC between systems. The enhancement from the FLSP surface is still attributed to increases in surface area and nucleation site density, but the source of the increase in HTCs for the dual-channel system over the single-channel system requires further study. Unlike location 4, the FLSP surface also brought notable enhancement to the CHF for both systems, with increases of 35% and 18% for the single- and the dual-channel systems, respectively. Due to the high wettability and augmented capillary action of the superhydrophilic FLSP surface, liquid was drawn to hot spots on the surface following nucleation, therefore delaying dryout. Combining the dual-channel system and the FLSP surface resulted in a 54% increase in the CHF over the single-channel system with the polished surface.

### Flow Stability

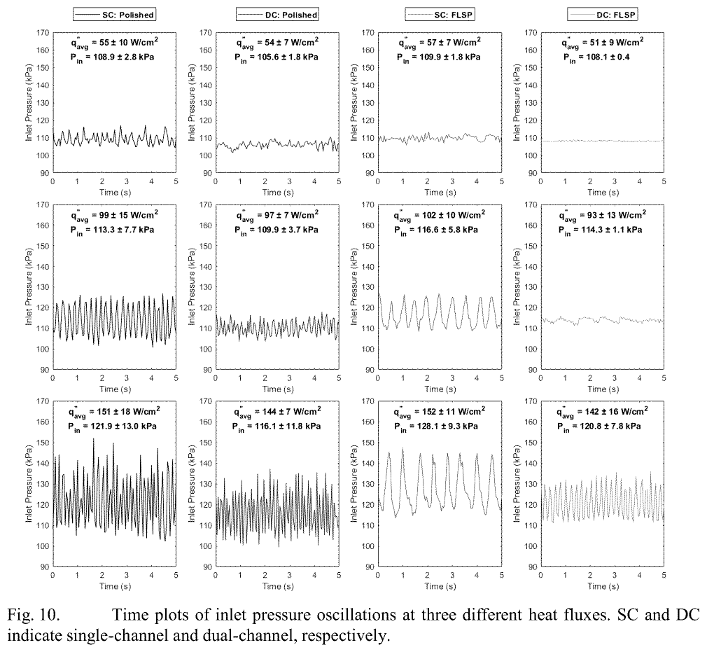

The inlet pressure oscillations are plotted vs time in FIG. 10 at three different levels of heat flux to illustrate the differences in behavior. Focusing on the polished surface, the dual-channel system reduced the average amplitude of the oscillations, but there was no obvious change in the frequency. For the single-channel system, the FLSP surface reduced the average amplitude of oscillations and the oscillation frequency compared to the polished surface. The reduction in frequency may be indicative that the release of many small bubbles delayed slug formation and thus upstream expansion, however, the same notable reduction in frequency did not occur for the FLSP surface in the dual-channel system. Rather, only a reduction in the average amplitude of oscillations was observed, yet that reduction was much more substantial in comparison.

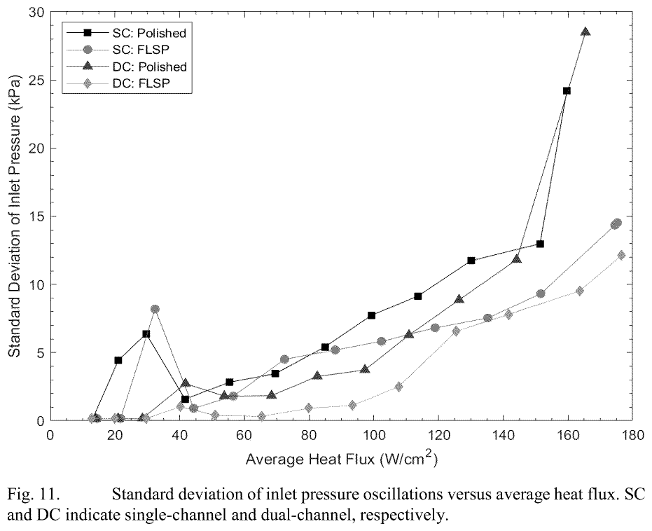

FIG. 11 shows the standard deviation of the inlet pressure oscillations as a function of heat flux. The standard deviation is used to represent the amplitude of the fluctuations. All four curves initially showed a spike in oscillation amplitude at the onset of nucleate boiling due to the compressible nature of generated bubbles. This spike was significantly reduced in the dual-channel system. For the polished surface, the dual-channel system also showed a reduction in oscillation amplitude across nearly all heat fluxes. It is hypothesized that the presence of the cold channel is actively condensing vapor formed on the boiling surface. Because the primary cause of pressure oscillations in small channels is the upstream expansion of vapor slugs, condensing vapor in the slugs would reduce the upstream expansion rate and, therefore, yield lower amplitude oscillations. The observed reduction in oscillation amplitude for the dual-channel system may also be caused by an increase in the degree of subcooling from interaction with the cold channel. Although there are conflicting reports on how subcooling affects flow stability, a recent study by Lee and Karayiannis found that increasing the degree of subcooling reduced pressure oscillations by delaying the formation of vapor slugs [19].

For the single-channel system, the FLSP surface exhibited a reduction in oscillation magnitude for most heat fluxes, despite the initial increase in magnitude at ONB. Because FLSP surfaces create many small bubbles rather than fewer, larger bubbles [13], it is hypothesized that the formation of fully confined vapor slugs responsible for upstream expansion became delayed, resulting in lower amplitude oscillations. Combining the dual-channel system with the FLSP surface yielded the largest reduction in oscillation amplitude for all heat fluxes.

In the above-mentioned study, two methods for flow boiling enhancement were tested for 304 stainless steel surfaces with water: femtosecond laser surface processing (FLSP) and a novel dual-channel flow boiling system. An FLSP surface and a polished baseline surface were tested in the dual-channel system and in a typical single-channel system. The following conclusions regarding embodiments herein were made:
1. Compared to the polished surface, the FLSP surface advantageously exhibited boiling inversion and an enhancement in the maximum HTC up to 225% and 845% for the single and dual-channel systems, respectively. The enhancement was attributed to an increase in surface area and potential nucleation sites created during laser processing.
2. For the FLSP surface, the dual-channel system showed advantageously higher degrees of boiling inversion and HTC enhancement over the single-channel system at elevated heat fluxes.
3. Compared to the single-channel system with the polished surface, individually replacing the polished surface with the FLSP surface and replacing the single-channel system with the dual-channel system advantageously yielded 35% and 30% increases in CHF, respectively, at location 6, the location furthest downstream from the inlet. Combining the two methods (dual-channel system with the FLSP surface) advantageously resulted in a 54% increase in CHF.
4. Reduction in the amplitude of inlet pressure oscillations was observed individually for the FLSP surface and the dual-channel system. For the FLSP surface, the reduction in amplitude is attributed to the release of many small bubbles as opposed to fewer, large bubbles, which delays the formation of confined vapor slugs. For the dual-channel system, the reduction in amplitude is attributed either to an increase in vapor condensation or an increase in the degree of subcooling. Combining the two yielded the greatest reduction in oscillation amplitude.

### REFERENCES

[1] G. Liang and I. Mudawar, “Review of channel flow boiling enhancement by surface modification, and instability suppression schemes,” Int. J. Heat Mass Transf., vol. 146, p. 118864, 2020, doi: 10.1016/j.ijheatmasstransfer.2019.118864.
[2] M. Law and P. S. Lee, “A comparative study of experimental flow boiling heat transfer and pressure characteristics in straight- and oblique-finned microchannels,” Int. J. Heat Mass Transf., vol. 85, pp. 797-810, 2015, doi: 10.1016/j.ijheatmasstransfer.2015.01.137.
[3] W. Wan, D. Deng, Q. Huang, T. Zeng, and Y. Huang, “Experimental study and optimization of pin fin shapes in flow boiling of micro pin fin heat sinks,” Appl. Therm. Eng., vol. 114, pp. 436-449, 2017, doi: 10.1016/j.applthermaleng.2016.11.182.
[4] C. Woodcock, C. Ng'oma, M. Sweet, Y. Wang, Y. Peles, and J. Plawsky, “Ultra-high heat flux dissipation with Piranha Pin Fins,” Int. J. Heat Mass Transf., vol. 128, pp. 504-515, 2019, doi: 10.1016/j.ijheatmasstransfer.2018.09.030. [5] D. Deng, W. Wan, Y. Qin, J. Zhang, and X. Chu, “Flow boiling enhancement of structured microchannels with micro pin fins,” Int. J. Heat Mass Transf., vol. 105, pp. 338-349, 2017, doi: 10.1016/j.ijheatmasstransfer.2016.09.086.
[6] F. Yang, W. Li, X. Dai, and C. Li, “Flow boiling heat transfer of HFE-7000 in nanowire-coated microchannels,” Appl. Therm. Eng., vol. 93, pp. 260-268, 2016, doi: 10.1016/j.applthermaleng.2015.09.097.
[7] A. K. M. M. Morshed, F. Yang, M. Yakut Ali, J. A. Khan, and C. Li, “Enhanced flow boiling in a microchannel with integration of nanowires,” Appl. Therm. Eng., vol. 32, no. 1, pp. 68-75, 2012, doi: 10.1016/j.applthermaleng.2011.08.031.
[8] A. K. M. M. Morshed, T. C. Paul, and J. Khan, “Effect of Cu-Al₂O₃ nanocomposite coating on flow boiling performance of a microchannel,” Appl. Therm. Eng., vol. 51, no. 1-2, pp. 1135-1143, 2013, doi: 10.1016/j.applthermaleng.2012.09.047.
[9] V. Khanikar, I. Mudawar, and T. Fisher, “Effects of carbon nanotube coating on flow boiling in a micro-channel,” Int. J. Heat Mass Transf., vol. 52, no. 15-16, pp. 3805-3817, 2009, doi: 10.1016/j.ijheatmasstransfer.2009.02.007.
[10] I. Pranoto and K. C. Leong, “An experimental study of flow boiling heat transfer from porous foam structures in a channel,” Appl. Therm. Eng., vol. 70, no. 1, pp. 100-114, 2014, doi: 10.1016/j.applthermaleng.2014.04.027.
[11] Y. Sun, L. Zhang, H. Xu, and X. Zhong, “Flow boiling enhancement of FC-72 from microporous surfaces in minichannels,” Exp. Therm. Fluid Sci., vol. 35, no. 7, pp. 1418-1426, 2011, doi: 10.1016/j.expthermflusci.2011.05.010.
[12] V. Y. S. Lee, G. Henderson, A. Reip, and T. G. Karayiannis, “Flow boiling characteristics in plain and porous coated microchannel heat sinks,” Int. J. Heat Mass Transf., vol. 183, 2022, doi: 10.1016/j.ijheatmasstransfer.2021.122152.
[13] C. M. Kruse et al., “Enhanced pool-boiling heat transfer and critical heat flux on femtosecond laser processed stainless steel surfaces,” Int. J. Heat Mass Transf., vol. 82, pp. 109-116, 2015, doi: 10.1016/j.ijheatmasstransfer.2014.11.023.
[14] C. Kruse et al., “Secondary pool boiling effects,” Appl. Phys. Lett., vol. 108, no. 5, 2016, doi: 10.1063/1.4941081.
[15] J. Costa-Greger et al., “Pool boiling heat transfer enhancement using femtosecond laser surface processed aluminum in saturated PF-5060,” Intersoc. Conf. Therm. Thermomechanical Phenom. Electron. Syst., 2022.
[16] K. Lim, K. Lee, H. Ki, and J. Lee, “Enhancement of flow boiling heat transfer by laser-induced periodic surface structures using femtosecond laser,” Int. J. Heat Mass Transf., vol. 196, p. 123229, 2022, doi: 10.1016/j.ijheatmasstransfer.2022.123229.
W. Qu and I. Mudawar, “Measurement and prediction of pressure drop in two-phase micro-channel heat sinks,” Int. J. Heat Mass Transf., vol. 46, no. 15, pp. 2737-2753, 2003, doi: 10.1016/S0017-9310 (03) 00044-9.
[18] J. Lee and I. Mudawar, “Fluid flow and heat transfer characteristics of low temperature two-phase micro-channel heat sinks-Part 1: Experimental methods and flow visualization results,” Int. J. Heat Mass Transf., vol. 51, no. 17-18, pp. 4315-4326, 2008, doi: 10.1016/j.ijheatmasstransfer.2008.02.012.
[19] V. Y. S. Lee and T. G. Karayiannis, “Effect of inlet subcooling on flow boiling in microchannels,” Appl. Therm. Eng., vol. 181, no. August, p. 115966, 2020, doi: 10.1016/j.applthermaleng.2020.115966.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the disclosed subject matter (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or example language (e.g., “such as”) provided herein, is intended merely to better illuminate the disclosed subject matter and does not pose a limitation on the scope of the invention unless otherwise claimed. No language in the specification should be construed as indicating any non-claimed element as essential to the practice of the invention.

Certain embodiments are described herein. Variations of those embodiments may become apparent to those of ordinary skill in the art upon reading the foregoing description. The inventors expect skilled artisans to employ such variations as appropriate, and the inventors intend for the embodiments to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

1. A dual-channel flow boiling device comprising:
a first fluid flow channel configured to receive a flow of a first fluid in a first direction;
a second fluid flow channel adjacent the first fluid flow channel and configured to receive a flow of a second fluid in a second direction; and
a separator condenser separating the first fluid flow channel and the second fluid flow channel, wherein the separator condenser has one or more functionalized surfaces, and wherein the separator condenser is integral to both the first fluid flow channel and the second fluid flow channel.

2. The device of claim 1, wherein the second fluid flow received at the second fluid flow channel is maintained at a lower temperature than the first fluid flow received at the first fluid flow channel to cause condensation of the first fluid in the first fluid flow channel.

3. The device of claim 1, wherein the one or more functionalized surfaces include micro-scale and nano-scale features formed by femtosecond laser surface processing (FLSP) or any other form of functionalization.

4. The device of claim 1, further including a heat source adjacent the first fluid flow channel, wherein a surface of the first fluid flow channel proximal to the heat source has a functionalized surface including micro-scale and nano-scale features formed by femtosecond laser surface processing (FLSP) or any other form of functionalization.

5. (canceled)

6. The device of claim 1, wherein the first fluid and the second fluid each comprise deionized water, a dielectric fluid or a refrigerant.

7. The device of claim 6, wherein the first fluid is different than the second fluid.

8. The device of claim 1, wherein the separator condenser comprises a metal material, a ceramic material or a plastic material.

9. (canceled)

10. The device of claim 1, wherein the flow of the second fluid in the second direction is opposite the flow of the first fluid in the first direction.

11. A method of transferring heat from a heat source using a dual-channel flow boiling structure having a first fluid flow channel configured to receive a flow of a first fluid in a first direction, a second fluid flow channel configured to receive a flow of a second fluid in a second direction, and a separator condenser separating the first fluid flow channel and the second fluid flow channel, wherein opposing sides of the separator condenser define a flow surface of the first fluid flow channel and a flow surface of the second fluid flow channel, wherein one or both opposing sides of the separator condenser has a functionalized surface that includes micro-scale and nano-scale features formed by femtosecond laser surface processing (FLSP) or any other functionalization technique, wherein the first fluid flow channel has a functionalized surface other than the flow surface defined by the separator condenser that includes micro-scale and nano-scale features formed by FLSP or any other functionalization technique, the method comprising:
positioning the dual-channel flow boiling structure proximal to a heat source such that the functionalized surface of the first fluid flow channel is located proximal to the heat source;
flowing the first fluid in the first fluid flow channel; and
simultaneously flowing the second fluid in the second fluid flow channel, wherein the second fluid received at the second fluid flow channel is maintained at a lower temperature than the first fluid received at the first fluid flow channel causing condensation on the flow surface of the separator condenser facing the first fluid flow channel.

12. The method of claim 11, wherein the micro-scale and nano-scale features of each functionalized surface have an average structure height of between about 40 μm to 50 μm, and an average roughness of from about 6 μm to about 7 μm.

13. The method of claim 11, wherein the first fluid and the second fluid each comprise deionized water, a dielectric fluid or a refrigerant.

14. The method of claim 13, wherein the first fluid is different than the second fluid.

15. The method of claim 11, wherein the separator condenser comprises a metal material, a ceramic material or a plastic material.

16. (canceled)

17. The method of claim 11, wherein the flow of the second fluid in the second direction is opposite the flow of the first fluid in the first direction.

18.-28. (canceled)

29. A dual-channel flow boiling system, the system comprising:
a dual-channel flow boiling device comprising:
a first fluid flow channel configured to receive a flow of a first fluid in a first direction;
a second fluid flow channel adjacent the first fluid channel and configured to receive a flow of a second fluid in a second direction; and
a separator condenser separating the first fluid flow channel and the second fluid flow channel, wherein opposing sides of the separator condenser define a flow surface of the first fluid flow channel and a flow surface of the second fluid flow channel;
wherein at least one of the opposing sides of the separator condenser has a functionalized surface that includes micro-scale and nano-scale features, or a surface of the first fluid flow channel other than the flow surface defined by the separator condenser is a functionalized surface that includes micro-scale and nano-scale features; and
at least one pump configured to generate a flow of a first fluid through the first fluid flow channel from a first fluid source, and to generate a flow of a second fluid through the second fluid flow channel from a second fluid source, wherein the second fluid source is maintained at a colder temperature than the first fluid source.

30. The system of claim 29, wherein one or both opposing sides of the separator condenser has a functionalized surface that includes micro-scale and nano-scale features formed by femtosecond laser surface processing (FLSP) or any other functionalization technique.

31. The system of claim 29, wherein one or both opposing sides of the separator condenser has a functionalized surface that includes micro-scale and nano-scale features formed by femtosecond laser surface processing (FLSP) or any other functionalization technique and the surface of the first fluid flow channel other than the flow surface defined by the separator condenser is a functionalized surface that includes micro-scale and nano-scale features formed by FLSP or any other functionalization technique.

32. The system of claim 29, wherein the flow of the second fluid in the second direction is opposite the flow of the first fluid in the first direction.

33. The system of claim 29, wherein the flow of the second fluid in the second direction is parallel to the flow of the first fluid in the first direction.

34. The system of claim 18, wherein the flow of the second fluid in the second direction is parallel to the flow of the first fluid in the first direction.

35. The device of claim 1, wherein the flow of the second fluid in the second direction is parallel to the flow of the first fluid in the first direction.
